(19) United States
(12) Patent Application Publication
(10) Pub. No.: US 2026/0234320 A1
(43) Pub. Date: Aug. 13, 2026

(54) EPOXY RESIN COMPOSITION FOR ENCAPSULATION OF SEMICONDUCTOR DEVICES AND SEMICONDUCTOR DEVICE ENCAPSULATED USING THE SAME

(71) Applicant: SAMSUNG SDI CO., LTD., Yongin-si (KR)

(72) Inventors: Tae Shin EOM, Suwon-si (KR); Dong Hwan LEE, Suwon-si (KR); Yong Han CHO, Suwon-si (KR); Jin A KIM, Suwon-si (KR)

(73) Assignee: SAMSUNG SDI CO., LTD., Yongin-si (KR)

(21) Appl. No.: 19/441,325

(22) Filed: Jan. 6, 2026

(30) Foreign Application Priority Data
Feb. 11, 2025 (KR) 10-2025-0017143

(51) Int. Cl. C08G 59/24; C08G 59/40; C08G 59/68; H10W 74/47

(52) U.S. Cl. CPC C08G 59/245; C08G 59/40; C08G 59/688; H10W 74/473

(57) ABSTRACT

An epoxy resin composition for encapsulation of semiconductor devices, and a semiconductor device encapsulated using the epoxy resin composition. The epoxy resin composition includes an epoxy resin, a curing agent, inorganic fillers, and a curing catalyst.

### CROSS-REFERENCE TO RELATED APPLICATION

The present application claims priority to Korean Patent Application No. 10-2025-0017143, filed on Feb. 11, 2025 in the Korean Intellectual Property Office, the entire disclosure of which is incorporated herein by reference.

### FIELD OF THE DISCLOSURE

The present disclosure relates to an epoxy resin composition for encapsulation of semiconductor devices, and a semiconductor device encapsulated using the epoxy resin composition.

### DESCRIPTION OF THE RELATED ART

The degree of integration of semiconductor devices is improving. In a semiconductor apparatus in which a stack of high-density semiconductor devices is encapsulated in a small and thin package, failure, such as cracking or malfunction of the package, can occur due to heat generation during operation of the semiconductor device.

As a solution to problems due to heat generation, a heatsink formed of or including a heat dissipation material, such as a metal, is bonded to a semiconductor package upon molding of an epoxy resin for encapsulation. However, such a heatsink is applicable only to some packages, such as, e.g., a fine pitch ball grid array (FBGA), a quad flat package (QFP), and the like, and has problems of reduction in productivity due to the need for additional assembly processes during assembly and increase in cost due to high costs of the heatsink. Therefore, there has been urgent demand for an epoxy resin molding material for encapsulation of semiconductor devices, which has high thermal conductivity and good heat dissipation capacity. Some semiconductor packages employ spherical aluminum oxide (alumina).

Alumina has a thermal conductivity in a range of about 25 W/m·K to about 30 W/m·K. However, an epoxy resin used for encapsulation of semiconductor devices has a substantially poor thermal conductivity of about 0.2 W/m·K.

### SUMMARY OF THE DISCLOSURE

It is one aspect of the present disclosure to provide an epoxy resin composition for encapsulation of semiconductor devices that has good fluidity, high thermal conductivity to improve heat dissipation in a semiconductor package, and high toughness to reduce or prevent breakage of a chip and cracking of the semiconductor package due to external impact and stress in reliability evaluation.

In accordance with one aspect of the present disclosure, there is provided an epoxy resin composition for encapsulation of semiconductor devices.

The epoxy resin composition for encapsulation of semiconductor devices includes an epoxy resin, a curing agent, inorganic fillers, and a curing catalyst, wherein the epoxy resin includes an epoxy resin represented by Formula 1:

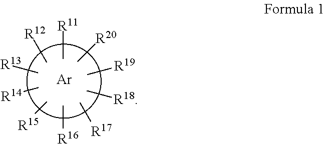

Ar is or includes anthracene or phenanthrene, and
R¹¹ to R²⁰ each independently is or includes hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, Formula 3, or Formula 4,
provided that at least one of R¹¹ to R²⁰ is or includes Formula 2, or
at least one of R¹¹ to R²⁰ is or includes Formula 3, and
at least two of R¹¹ to R²⁰ are or include Formula 4.

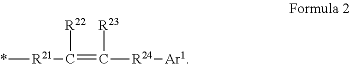

* is a linking site of an element,
R²¹ and R²⁴ each independently is or includes a single bond or a substituted or unsubstituted C₁ to C₅ alkylene group,
R²² and R²³ each independently is or includes hydrogen or a substituted or unsubstituted C₁ to C₅ alkyl group, and
Ar¹ is or includes a substituted or unsubstituted C₆ to C₁₀ aryl group.

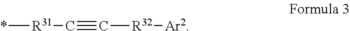

* is a linking site of an element,
R³¹ and R³² independently is or includes a single bond or a substituted or unsubstituted C₁ to C₅ alkylene group, and
Ar² is or includes a substituted or unsubstituted C₆ to C₁₀ aryl group.

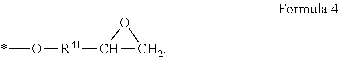

* is a linking site of an element, and
R⁴¹ is or includes a single bond or a substituted or unsubstituted C₁ to C₂₀ alkylene group.

In accordance with another aspect of the present disclosure, there is provided a semiconductor device.

The semiconductor device is encapsulated with the epoxy resin composition for encapsulation of semiconductor devices.

Example embodiments of the present disclosure include an epoxy resin composition for encapsulation of semiconductor devices that has good fluidity to allow easy encapsulation of semiconductor devices, exhibits good heat dissipation to reduce or suppress package malfunction and failure due to heat, and can reduce or suppress chip breakage and cracking of a semiconductor package due to external impact and stress in reliability evaluation.

### DETAILED DESCRIPTION OF THE DISCLOSURE

Hereinafter, example embodiments of the present disclosure are described in detail such that the present disclosure can be readily implemented by a person having ordinary knowledge in the art. It should be understood that the present disclosure may be embodied in various ways and is not limited to the following example embodiments.

As used herein to represent a specific numerical range, “X to Y” means “greater than or equal to X and less than or equal to Y”.

As used herein, the term “substituted” in the expression “substituted or unsubstituted” means that at least one hydrogen atom of a corresponding functional group is substituted with a hydroxyl group, an amino group, a nitro group, a cyano group, a C₁ to C₂₀ alkyl group, a C₁ to C₂₀ haloalkyl group, a C₆ to C₃₀ aryl group, a C₃ to C₃₀ heteroaryl group, a C₃ to C₁₀ cycloalkyl group, a C₃ to C₁₀ heterocycloalkyl group, a C₇ to C₃₀ arylalkyl group, or a C₁ to C₃₀ heteroalkyl group.

As used herein, “hetero” may refer to nitrogen, oxygen, or sulfur.

Unless stated otherwise, a formula described herein may be considered to have a hydrogen atom bonded to a structure thereof.

When the terms “about” or “substantially” are used in this specification in connection with a numerical value, it is intended that the associated numerical value include a tolerance of ±10% around the stated numerical value. The expression “up to” includes amounts of zero to the expressed upper limit and all values therebetween. When ranges are specified, the range includes all values therebetween such as increments of 0.1%.

An epoxy resin composition for encapsulation of semiconductor devices according to one example embodiment may have good fluidity to facilitate encapsulation of the semiconductor devices. The epoxy resin composition may have high thermal conductivity to improve heat dissipation from a semiconductor package, thereby reducing or suppressing malfunction and failure of the semiconductor package due to heat. The epoxy resin composition has high toughness to reduce or suppress breakage of a chip and cracking in a semiconductor package due to external impact and stress in reliability evaluation.

The epoxy resin composition for encapsulation of semiconductor devices includes an epoxy resin, a curing agent, inorganic fillers, and a curing catalyst, wherein the epoxy resin includes an epoxy resin represented by Formula 1. The epoxy resin represented by Formula 1 may provide the aforementioned effects.

### Epoxy Resin

The epoxy resin includes an epoxy resin represented by Formula 1. The epoxy resin represented by Formula 1 can provide an epoxy resin composition for encapsulation of semiconductor devices that has low viscosity to provide good fluidity, and has high thermal conductivity and high toughness to secure the aforementioned effects.

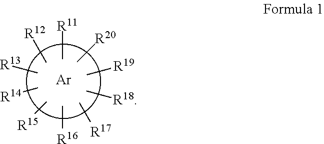

Ar is or includes anthracene or phenanthrene, and
R¹¹ to R²⁰ each independently is or includes hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, Formula 3, or Formula 4,
provided that at least one of R¹¹ to R²⁰ is or includes Formula 2, or
at least one of R¹¹ to R²⁰ is or includes Formula 3, and
at least two of R¹¹ to R²⁰ are or include Formula 4.

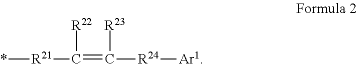

* is a linking site of an element,
R²¹ and R²⁴ each independently is or includes a single bond or a substituted or unsubstituted C₁ to C₅ alkylene group,
R²² and R²³ each independently is or includes hydrogen or a substituted or unsubstituted C₁ to C₈ alkyl group, and
Ar¹ is or includes a substituted or unsubstituted C₆ to C₁₀ aryl group.

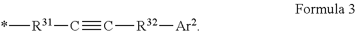

* is a linking site of an element,
R³¹ and R³² independently is or includes a single bond or a substituted or unsubstituted C₁ to C₅ alkylene group, and
Ar² is or includes a substituted or unsubstituted C₆ to C₁₀ aryl group.

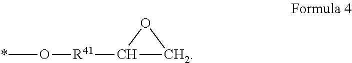

* is a linking site of an element, and
R⁴¹ is or includes a single bond or a substituted or unsubstituted C₁ to C₂₀ alkylene group.

In one example embodiment, R¹¹ to R²⁰ may each independently be or include hydrogen, a substituted or unsubstituted C₁ to C₁₀ alkyl group, Formula 2, Formula 3, or Formula 4, in which at least one of R¹¹ to R²⁰ may be Formula 2, or at least one of R¹¹ to R²⁰ may be Formula 3 and at least two of R¹¹ to R²⁰ may be Formula 4.

In one example embodiment, Ar¹ in Formula 2 may be or include a substituted or unsubstituted, phenyl or naphthyl group and Ar² in Formula 3 may be or include a substituted or unsubstituted, phenyl or naphthyl group.

In one example embodiment, in Formula 4, R⁴¹ may be or include a substituted or unsubstituted C₃ to C₁₅ alkylene group, for example, a substituted or unsubstituted C₄ to C₁₀ alkylene group.

For example, the epoxy resin may include at least one compound represented by Formula 1-1:

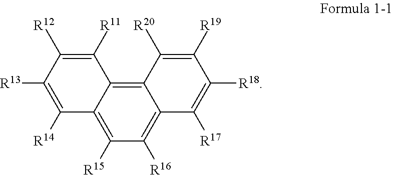

R¹¹ to R²⁰ are each independently the same as R¹¹ to R²⁰ defined in Formula 1.

For example, the epoxy resin may include at least one compound represented by Formula 1-2:

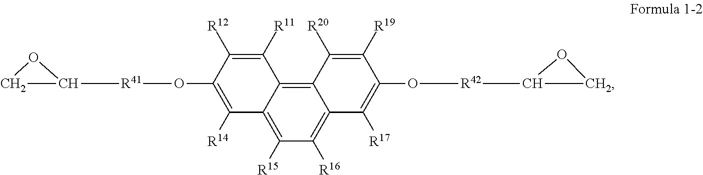

R¹¹, R¹², R¹⁴, R¹⁵, R¹⁶, R¹⁷, R¹⁹, and R²⁰ each independently is or includes hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, or Formula 3,
provided that at least one of R¹¹, R¹², R¹⁴, R¹⁵, R¹⁶, R¹⁷, R¹⁹, and R²⁰ is or includes Formula 2, or at least one of R¹¹, R¹², R¹⁴, R¹⁵, R¹⁶, R¹⁷, R¹⁹, and R²⁰ is or includes Formula 3, and
R⁴¹ and R⁴² each independently is or includes a single bond or a substituted or unsubstituted C₁ to C₂₀ alkylene group.

In one example embodiment, R⁴¹ and R⁴² may be or include a substituted or unsubstituted, C₃ to C₁₅ alkylene group, for example, a substituted or unsubstituted, C₄ to C₁₀ alkylene group.

In one example embodiment, R¹⁴ and R¹⁷ may be or include Formula 2 or Formula 3, for example Formula 3.

In one example embodiment, R¹⁵ and R¹⁶ may be or include Formula 2 or Formula 3, for example Formula 3.

In one example embodiment, Ar¹ in Formula 2 may be or include a substituted or unsubstituted, phenyl or naphthyl group and Ar² in Formula 3 may be or include a substituted or unsubstituted, phenyl or naphthyl group.

For example, the epoxy resin may include at least one compound represented by Formula 1-3:

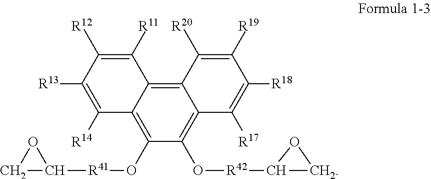

R¹¹, R¹², R¹³, R¹⁴, R¹⁷, R¹⁸, R¹⁹, and R²⁰ each independently is or includes hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, or Formula 3,
provided that at least one of R¹¹, R¹², R¹³, R¹⁴, R¹⁷, R¹⁸, R¹⁹, and R²⁰ is or includes Formula 2 or at least one of R¹¹, R¹², R¹³, R¹⁴, R¹⁷, R¹⁸, R¹⁹, and R²⁰ is or includes Formula 3, and
R⁴¹ and R⁴² each independently is or includes a single bond or a substituted or unsubstituted C₁ to C₂₀ alkylene group.

In one example embodiment, R⁴¹ and R⁴² may be or include a substituted or unsubstituted C₃ to C₁₅ alkylene group, for example, a substituted or unsubstituted C₄ to C₁₀ alkylene group.

In one example embodiment, R¹³ and R¹⁸ may be or include Formula 2 or Formula 3, for example Formula 3.

In one example embodiment, R¹² and R¹⁹ may be or include Formula 2 or Formula 3, for example Formula 3.

In one example embodiment, Ar¹ in Formula 2 may be or include a substituted or unsubstituted, phenyl or naphthyl group and Ar² in Formula 3 may be or include a substituted or unsubstituted, phenyl or naphthyl group.

In one example embodiment, the epoxy resin may include at least one compound represented by Formula 1-4:

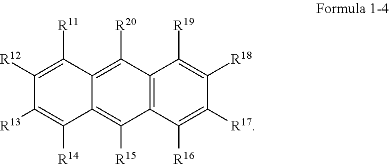

R¹¹ to R²⁰ each independently is or includes the same as R¹¹ to R²⁰ defined in Formula 1.

In one example embodiment, the epoxy resin may include at least one compound represented by Formula 1-5:

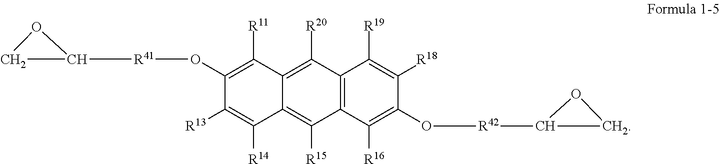

R¹¹, R¹³, R¹⁴, R¹⁵, R¹⁶, R¹⁸, R¹⁹, and R²⁰ each independently is or includes hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, or Formula 3,
provided that at least one of R¹¹, R¹³, R¹⁴, R¹⁵, R¹⁶, R¹⁸, R¹⁹, and R²⁰ is or includes Formula 2 or,
at least one of R¹¹, R¹³, R¹⁴, R¹⁵, R¹⁶, R¹⁸, R¹⁹, and R²⁰ is or includes Formula 3, and
R⁴¹ and R⁴² each independently is or includes a single bond or a substituted or unsubstituted C₁ to C₂₀ alkylene group.

In one example embodiment, R⁴¹ and R⁴² may be or include a substituted or unsubstituted C₃ to C₁₅ alkylene group, for example, a substituted or unsubstituted C₄ to C₁₀ alkylene group.

In one example embodiment, R¹¹ and R¹⁶ may be or include Formula 2 or Formula 3, for example Formula 3.

In one example embodiment, R¹³ and R¹⁸ may be or include Formula 2 or Formula 3, for example Formula 3.

In one example embodiment, R¹⁵ and R²⁰ may be or include Formula 2 or Formula 3, for example Formula 3.

In one example embodiment, Ar¹ in Formula 2 may be or include a substituted or unsubstituted, phenyl or naphthyl group and Ar² in Formula 3 may be or include a substituted or unsubstituted, phenyl or naphthyl group.

In one example embodiment, the epoxy resin may include at least one of compounds represented by Formulas 1-6 through 1-17. Formula 1-6:

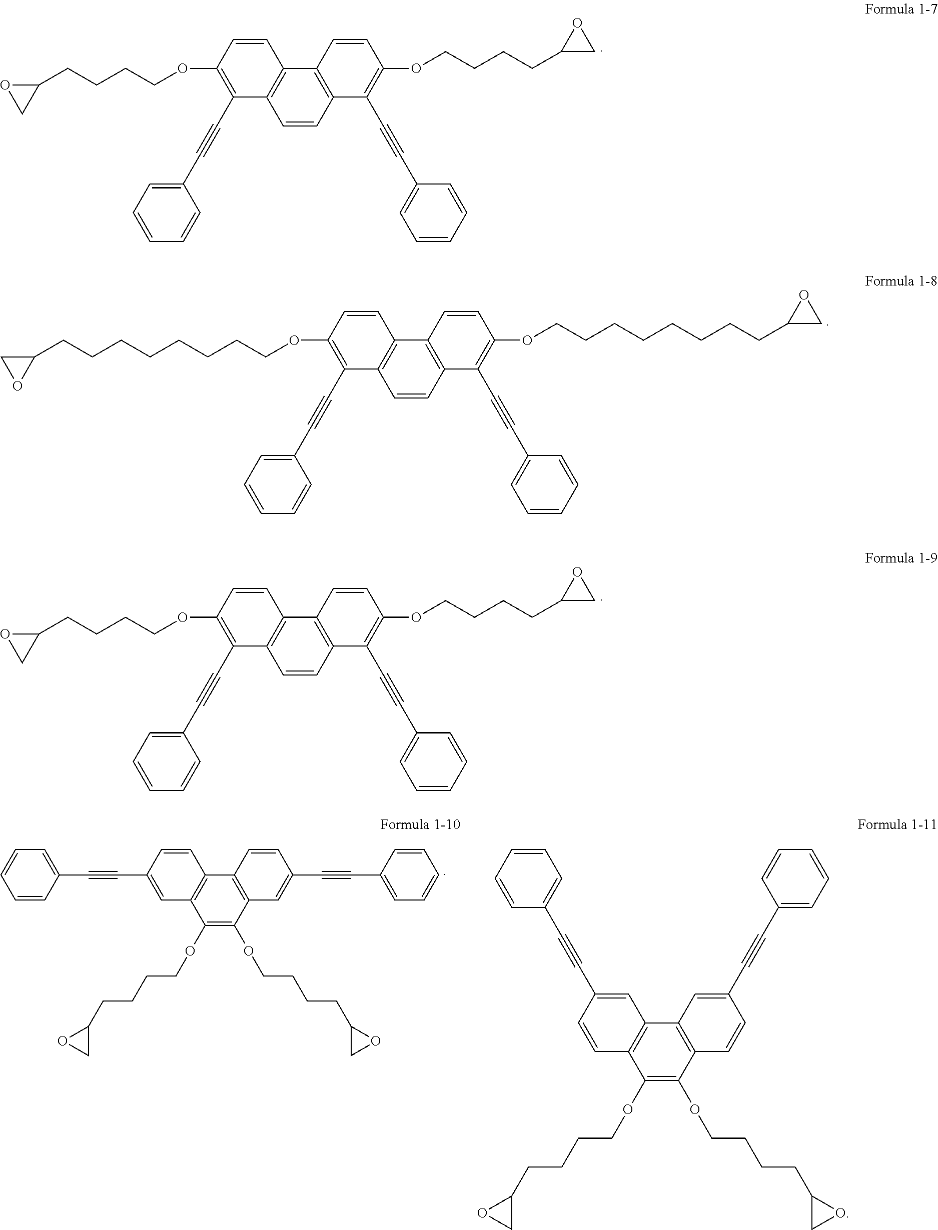 [SMILES: C(#Cc1c(OCCCCC2CO2)ccc2c1ccc1c(C#Cc3ccccc3)c(OCCCCC3CO3)ccc12)c1ccccc1 ; C(#Cc1c(OCCCCCCCCC2CO2)ccc2c1ccc1c(C#Cc3ccccc3)c(OCCCCCCCCC3CO3)ccc12)c1ccccc1 ; C(#Cc1c(OCCCCC2CO2)ccc2c1ccc1c(C#Cc3ccccc3)c(OCCCCC3CO3)ccc12)c1ccccc1 ; C(#Cc1ccc2c(c1)c(OCCCCC1CO1)c(OCCCCC1CO1)c1cc(C#Cc3ccccc3)ccc12)c1ccccc1 ; C(#Cc1ccc2c(OCCCCC3CO3)c(OCCCCC3CO3)c3ccc(C#Cc4ccccc4)cc3c2c1)c1ccccc1]

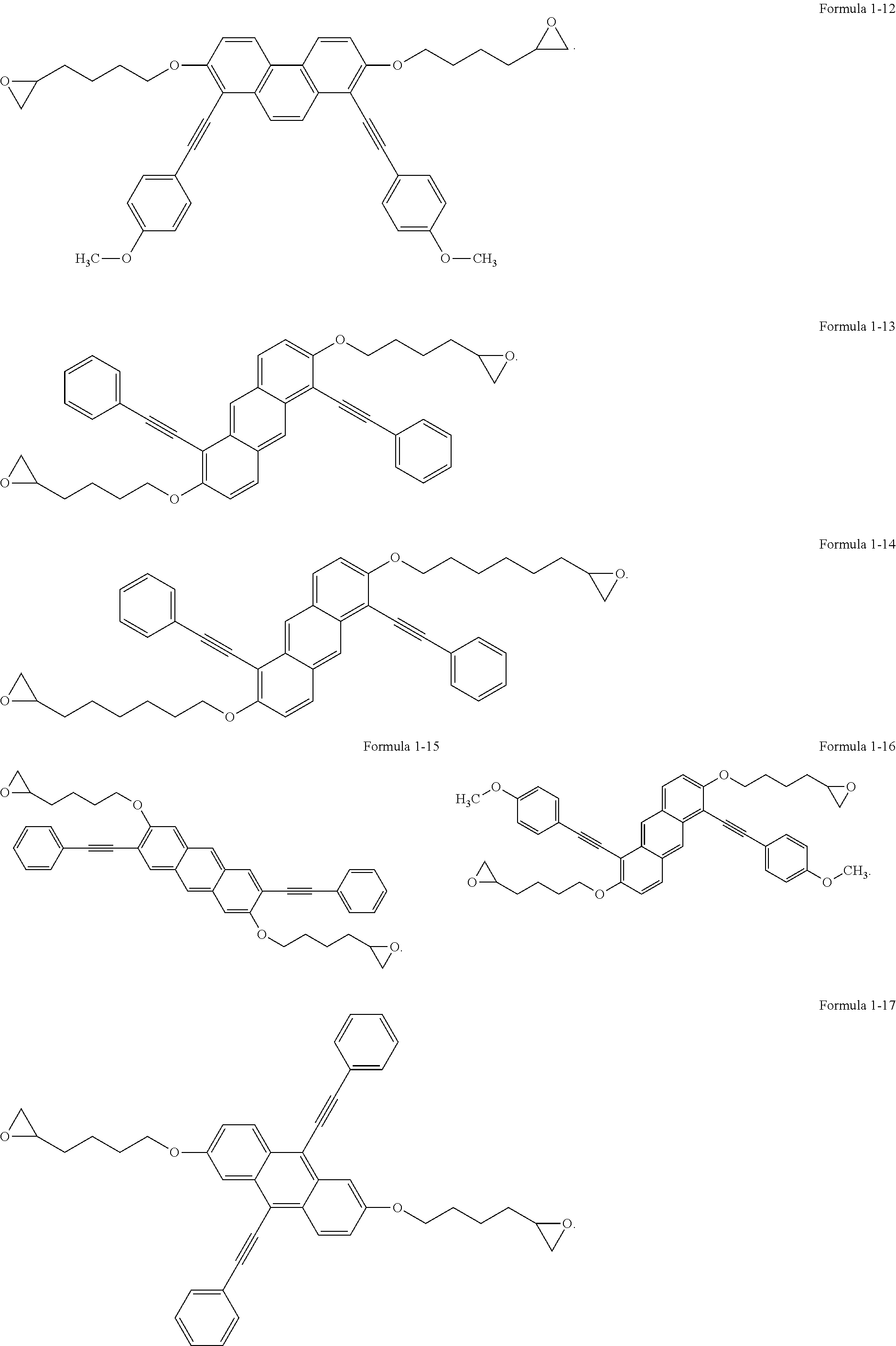

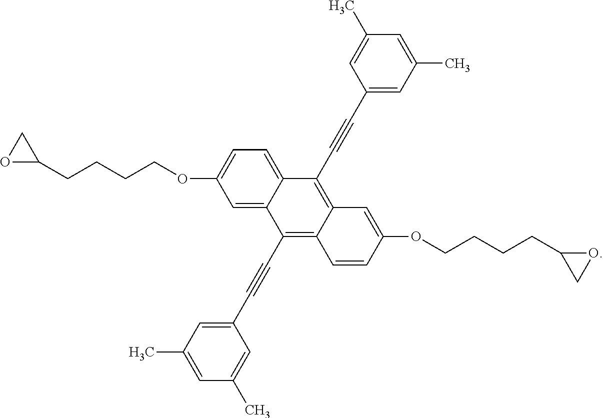 [SMILES: Cc1cc(C)cc(C#Cc2c3ccc(OCCCCC4CO4)cc3c(C#Cc3cc(C)cc(C)c3)c3ccc(OCCCCC4CO4)cc23)c1]

The epoxy resin represented by Formula 1 may be included singularly or in plural and may be present in an amount in a range of about 0.1 wt % to about 17 wt %, for example, 2 wt % to 17 wt %, or 2 wt % to 10 wt %, in the epoxy resin composition. Within this range, the epoxy resin composition can improve heat dissipation properties without deterioration in curability.

The epoxy resin represented by Formula 1 may be prepared by a typical method for preparing an epoxy resin known to those skilled in the art with reference to Formula 1.

For example, the epoxy resin represented by Formula 1 may be prepared with reference to the following Reaction 1:

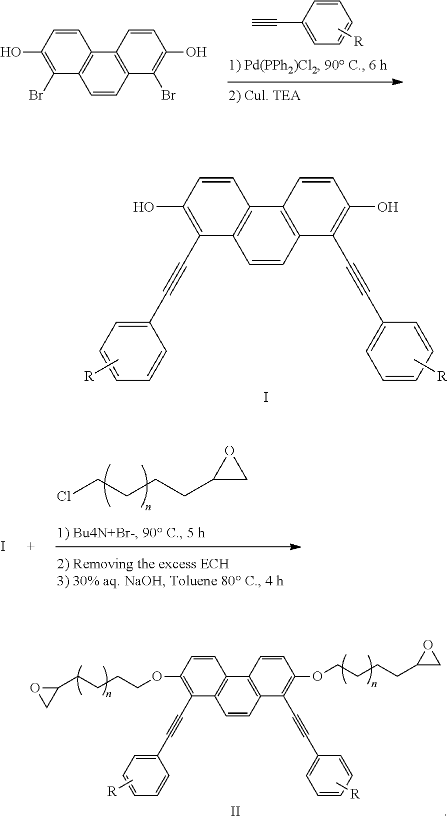

For example, the epoxy resin represented by Formula 1 may be prepared with reference to the following Reaction 2:

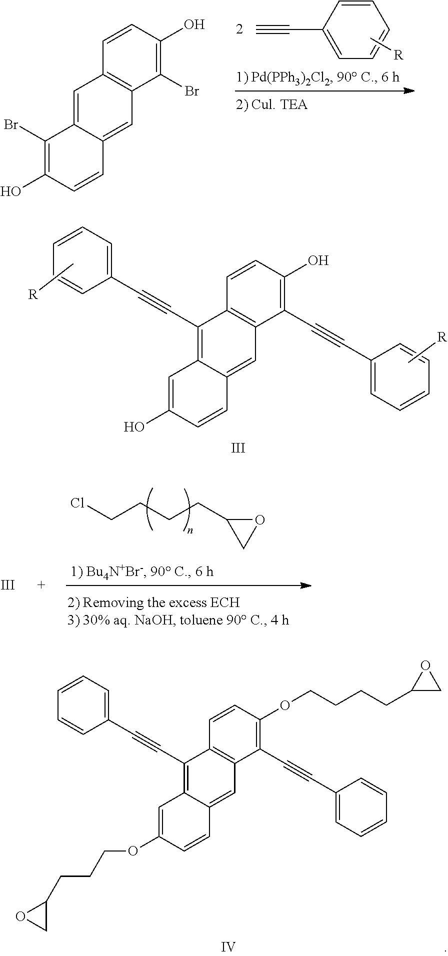

The epoxy resin of the epoxy resin composition may consist of or include the epoxy resin represented by Formula 1. However, the present disclosure is not limited thereto and the epoxy resin composition may further include an epoxy resin other than the epoxy resin represented by Formula 1 without affecting the effects of the present disclosure. For convenience, the epoxy resin represented by Formula 1 is referred to as a first epoxy resin, and the epoxy resin other than the epoxy resin represented by Formula 1 is referred to as a second epoxy resin.

The second epoxy resin is an epoxy resin containing at least two epoxy groups in a molecular structure thereof, and may include at least one of bisphenol A type epoxy resins, bisphenol F type epoxy resins, phenol novolac type epoxy resins, tert-butyl catechol type epoxy resins, naphthalene type epoxy resins, glycidyl amine type epoxy resins, cresol novolac type epoxy resins, biphenyl type epoxy resins, phenol aralkyl type epoxy resins, linear aliphatic epoxy resins, alicyclic epoxy resins, heterocyclic epoxy resins, spirocyclic epoxy resins, cyclohexanedimethanol type epoxy resins, trimethylol type epoxy resins, halogenated epoxy resins, and the like. As the second epoxy resin, these epoxy resins may be used alone or as a mixture thereof.

The epoxy resin may be present in an amount in a range of about 2 wt % to about 17 wt %, for example, 2 wt % to 10 wt %, in the epoxy resin composition. Within this range, the composition can avoid deterioration in curability.

### Curing Agent

The curing agent may include at least one of polyfunctional phenol resins, phenol aralkyl type phenol resins, phenol novolac type phenol resins, Xylok type phenol resins, cresol novolac type phenol resins, naphthol-type phenol resins, terpene-type phenol resins, dicyclopentadiene phenol resins, novolac type phenol resins synthesized from bisphenol A and resol, and the like; polyhydric phenol compounds including tris(hydroxyphenyl) methane, dihydroxybiphenyl, and the like; acid anhydrides including maleic anhydride, phthalic anhydride, and the like; and aromatic amines including metaphenylenediamine, diaminodiphenylmethane, diaminodiphenylsulfone, and the like. For example, the curing agent includes a Xylok type phenol resin or a phenol aralkyl type phenol resin.

The curing agent may be present in an amount in a range of about 0.5 wt % to about 13 wt % in the epoxy resin composition. Within this range, the epoxy resin composition can reduce or avoid deterioration in curability.

### Inorganic Fillers

The one or more inorganic fillers improve mechanical properties of the epoxy resin composition while reducing internal stress of the epoxy resin composition.

The inorganic fillers may include at least one of fused silica, crystalline silica, calcium carbonate, magnesium carbonate, alumina, magnesia, clay, talc, calcium silicate, titanium oxide, antimony oxide, and glass fiber.

For example, the inorganic fillers include fused silica having a low coefficient of linear expansion for low stress. The fused silica refers to amorphous silica having a specific gravity of about 2.3 or less and may include amorphous silica obtained by melting crystalline silica or synthesized from various raw materials. Although the fused silica is not limited to a particular shape and size, the inorganic fillers may include a range of about 40 wt % to about 100 wt % of a fused silica mixture including about 50 wt % to about 99 wt % of spherical fused silica having an average particle diameter in a range of about 5 μm to about 30 μm, and in a range about 1 wt % to about 50 wt % of spherical fused silica having an average particle diameter in a range of about 0.001 μm to about 1 μm. Furthermore, the maximum particle diameter of the inorganic fillers may be adjusted to about 45 μm, about 55 μm, about 75 μm, and the like depending on application.

The content of the inorganic fillers in the epoxy resin composition may be varied depending on properties required for the composition, such as thermal conductivity, moldability, low stress, and strength at high temperature. In some example embodiments, the inorganic fillers may be present in an amount in a range of about 50 wt % to about 95 wt %, for example 70 wt % to 95 wt %, or for example 85 wt % to 95 wt %, in the epoxy resin composition. Within this range, the epoxy resin composition can have good properties in terms of flame retardancy, fluidity, and reliability.

### Curing Catalyst

The curing catalyst may include at least one of a tertiary amine compound, an organometallic compound, an organophosphorus compound, an imidazole compound, or a boron compound. The tertiary amine compound may include, for example, at least one of benzyldimethylamine, triethanolamine, triethylenediamine, diethylaminoethanol, tri(dimethylaminomethyl)phenol, 2,2-(dimethylaminomethyl)phenol, 2,4,6-tris(diaminomethyl)phenol, tri-2-ethyl hexanoate, and the like. The organometallic compound may include, for example, at least one of chromium acetylacetonate, zinc acetylacetonate, nickel acetylacetonate, and the like. The organophosphorus compound may include, for example, at least one of triphenylphosphine, tris-4-methoxyphosphine, triphenylphosphine-triphenylborane, triphenylphosphine-1,4-benzoquinone adducts, and the like. The imidazole compound may include, for example, at least one of 2-methylimidazole, 2-phenylimidazole, 2-aminoimidazole, 2-methyl-1-vinylimidazole, 2-ethyl-4-methylimidazole, 2-heptadecyl imidazole, and the like. The boron compound may include, for example, at least one of triphenylphosphine tetraphenyl borate, tetraphenylboron salts, trifluoroborane-n-hexylamine, trifluoroborane monoethylamine, tetrafluoroborane triethylamine, tetrafluoroborane amine, and the like. Besides these compounds, at least one of 1,5-diazabicyclo4.3.0: non-5-ene (DBN), 1,8-diazabicyclo5.4.0: undec-7-ene (DBU), and phenol novolac resin salts may be used as the curing catalyst.

The curing catalyst may be provided in the form of an adduct prepared by pre-reacting the curing catalyst with the epoxy resin or the curing agent.

The curing catalyst may be present in an amount in a range of about 0.01 wt % to about 5 wt % in the epoxy resin composition. Within this range, the curing catalyst can promote curing of the composition without sacrificing fluidity of the composition.

The epoxy resin composition may further include typical additives used in epoxy resin compositions for encapsulation of semiconductor devices. In some example embodiments, the additives may include at least one of a coupling agent, a release agent, a colorant, a stress relieving agent, a crosslinking enhancer, and a leveling agent.

The coupling agent increases interfacial strength between the epoxy resin and the inorganic fillers through reaction with the epoxy resin and the inorganic fillers and may include, for example, a silane coupling agent. The silane coupling agent may include any silane coupling agent capable of increasing interfacial strength between the epoxy resin and the inorganic fillers through reaction with the epoxy resin and the inorganic fillers, without limitation. The silane coupling agent may include, for example, at least one of epoxy silane, amino silane, ureido silane, mercapto silane, alkyl silane, and the like. These coupling agents may be used alone or in combination thereof. The coupling agent may be present in an amount 15 in a range of about 0.01 wt % to about 5 wt %, for example 0.05 wt % to 3 wt %, in the epoxy resin composition for encapsulation of semiconductor devices. Within this range, a cured product of the epoxy resin composition can have enhanced strength.

The release agent may include at least one of paraffin wax, ester wax, higher fatty acid, metallic salts of higher fatty acid, natural fatty acid, and metallic salts of natural fatty acid. The release agent may be present in an amount in a range of about 0.1 wt % to about 1 wt % in the epoxy resin composition.

The colorant may include carbon black. The colorant may be present in an amount in a range of about 0.1 wt % to about 1 wt % in the epoxy resin composition.

The stress relieving agent may include at least one of modified silicone oils, silicone elastomers, silicone powder, and silicone resins, without being limited thereto. The stress relieving agent may be optionally present in an amount in a range of about 0 wt % to about 2 wt %, for example, 0 wt % to 1 wt %, or for example 0.1 wt % to 1 wt %, in the epoxy resin composition.

The additives may be present in an amount in a range of about 0.1 wt % to about 5 wt %, for example, 0.1 wt % to 3 wt %, in the epoxy resin composition.

Although a method of preparing the epoxy resin composition is not limited to a particular method, the epoxy resin composition may be prepared by uniformly, or substantially uniformly, mixing the aforementioned components in a Henschel mixer or a Lödige mixer, melt-kneading the mixture in a roll mill or a kneader at a temperature in a range of about 90° C. to about 120° C., and subjecting the reaction product to cooling and pulverization.

In accordance with another aspect of the present disclosure, a semiconductor device is encapsulated with the epoxy resin composition for encapsulation of semiconductor devices according to the present disclosure. The semiconductor device may be encapsulated with the epoxy resin composition by any suitable method known in the art, such as, e.g., transfer molding, injection molding, casting, or compression molding, without being limited thereto. In one example embodiment, the semiconductor device may be encapsulated with the epoxy resin composition by low-pressure transfer molding. In another example embodiment, the semiconductor device may be encapsulated with the epoxy resin composition by compression molding.

Next, the present disclosure is described in more detail with reference to some examples. However, it should be noted that these examples are provided for illustration only and are not to be construed in any way as limiting the present disclosure.

### Preparative Example 1: Preparation of Epoxy Resin

In a 250 ml flask, 1,8-dibromo-2,7-phenanthrenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 1,8-bis(phenylethynyl)-2,7-phenanthrenediol (E1). In the presence of TBAB (26 g, 0.1 mol) (tetra-n-butylammonium bromide) and an excess (300 g) of 2-(4-chlorobutyl)oxirane, E1 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-6 in 70% yield through intramolecular Williamson ether synthesis. ¹H NMR (400 MHz, CDCl₃) δ 8.75 (dd, 2H), 7.71 (s, 2H), 7.46 (m, 4H), 7.35 (m, 2H), 7.23-7.18 (m, 6H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 160.2, 132.3, 132.2,131.1, 131.0, 128.5, 128.4, 128.3, 126.6, 122.7, 122.6, 122.5, 109.2, 107.8, 92.9, 92.8, 68.9, 68.8, 52.3, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.41; H, 6.39.

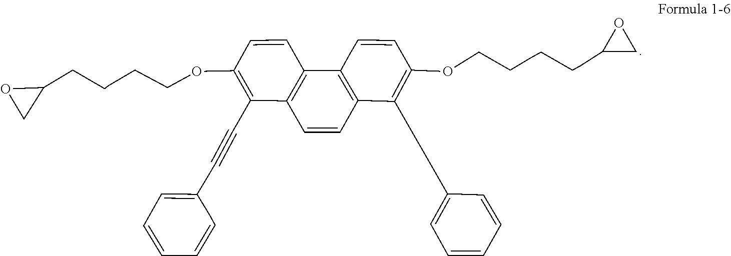 [SMILES: C(#Cc1c(OCCCCCC2CO2)ccc2c3c(ccc12)C(c1ccccc1)=C(OCCCCCCC1CO1)C=CC3)C1=CC=CC=CC1]

### Preparative Example 2: Preparation of Epoxy Resin

In a 250 ml flask, 1,8-dibromo-2,7-phenanthrenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 ml of diethyl ether was added to the reaction product to produce a soluble material, followed by removing the solvent therefrom, thereby preparing 1,8-bis(phenylethynyl)-2,7-phenanthrenediol (E2). In the presence of with TBAB (26 g, 0.1 mol) and an excess (320 g) of 2-(8-chlorooctyl)oxirane, E2 (21 g, 0.05 mol) was heated (to 90° C.) under solvent-free conditions for 6 hours and cooled to room temperature, followed by removing the remaining 2-(8-chlorooctyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-7 in 60% yield. ¹H NMR (400 MHz, CDCl₃) δ 8.75 (dd, 2H), 7.71 (s, 2H), 7.46 (m, 4H), 7.35 (m, 2H), 7.23-7.18 (m, 6H), 4.04 (m, 4H), 2.63-2.38 (m, 6H) 1.71 (m, 4H) 1.42 (m, 4H), 1.30-1.25 (m, 16H) ppm; ¹³C NMR (100 MHz, CDCl₃) δ 160.3, 132.3, 132.2, 131.1, 131.0, 128.5, 128.4, 128.3, 128.2, 126.7, 122.7 122.6, 122.4, 122.3, 109.2, 107.8, 92.9, 92.8, 68.9, 52.3, 47.9, 33.5, 33.2, 29.7, 29.4, 26.0, 25.3, ppm; GC-MS m/z=718 (M+); Anal. Calcd for C₅₀H₅₄O₄: C, 83.53; H, 7.57. Found: C, 83.49; H, 7.31.

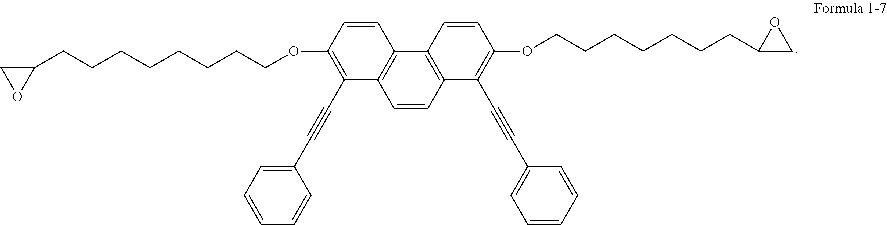 [SMILES: C(#Cc1c(OCCCCCCCCC2CO2)ccc2c1ccc1c(C#Cc3ccccc3)c(OCCCCCCCC3CO3)ccc12)c1ccccc1]

### Preparative Example 3: Preparation of Epoxy Resin

In a 250 ml flask, 9,10-dibromo-2,7-phenanthrenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 9,10-bis(phenylethynyl)-2,7-phenanthrenediol (E3). In the presence of TBAB (26 g, 0.1 mol) and an excess (300 g) of 2-(4-chlorobutyl)oxirane, E3 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-8 in 75% yield. ¹H NMR (400 MHz, CDCl₃) δ 8.82 (dd, 2H), 7.63 (s, 2H), 7.46-7.35 (m, 4H), 7.23-7.18 (m, 6H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 155.2, 132.3, 132.2, 130.7, 128.5, 128.4, 128.3, 124.0, 123.0, 122.7, 122.4, 111.2, 109.6, 92.9, 92.8, 68.9, 52.3, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.31; H, 6.66.

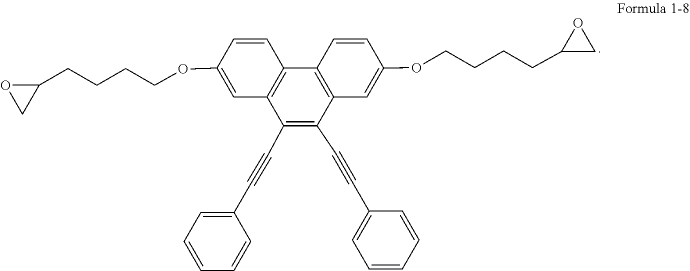 [SMILES: C(#Cc1c(C#Cc2ccccc2)c2cc(OCCCCC3CO3)ccc2c2ccc(OCCCCC3CO3)cc12)c1ccccc1]

### Preparative Example 4: Preparation of Epoxy Resin

In a 250 ml flask, 2,7-dibromo-9,10-phenanthrenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 2,7-bis(phenylethynyl)-9,10-phenanthrenediol (E4). In the presence of TBAB (26 g, 0.1 mol) and an excess (300 g) of 2-(4-chlorobutyl)oxirane, E4 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating (to 90° C.) for 4 hours, thereby preparing an epoxy resin represented by Formula 1-9 in 75% yield. ¹H NMR (400 MHz, CDCl₃) δ 8.89 (dd, 2H), 8.32 (s, 2H), 8.08 (m, 2H), 7.46 (m, 4H), 7.23-7.18 (m, 6H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 148.9, 132.3, 132.2, 131.9, 131.8, 128.5, 128.4, 128.3, 123.3, 123.2, 122.0, 121.9, 120.1, 92.9, 92.8, 68.9, 52.3, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.50; H, 6.54.

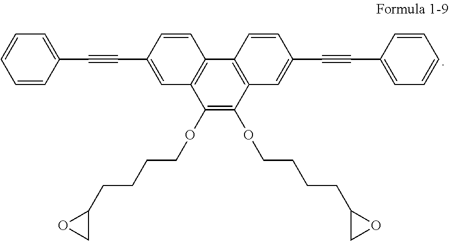 [SMILES: C(#Cc1ccc2c(c1)c(OCCCCC1CO1)c(OCCCCC1CO1)c1cc(C#Cc3ccccc3)ccc12)c1ccccc1]

### Preparative Example 5: Preparation of Epoxy Resin

In a 250 ml flask, 3,6-dibromo-9,10-phenanthrenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 3,6-bis(phenylethynyl)-9,10-phenanthrenediol (E5). In the presence of TBAB (26 g, 0.1 mol) and an excess (300 g) of 2-(4-chlorobutyl)oxirane, E5 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-10 in 75% yield. ¹H NMR (400 MHz, CDCl3) δ 9.13 (s, 2H), 8.08-8.02 (m, 4H), 7.46 (m, 4H), 7.23-7.18 (m, 6H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 148.9, 132.3, 132.2, 131.9, 131.8, 128.5, 128.4, 128.3, 127.9, 126.0, 123.3, 123.2, 122.7, 122.6, 120.1, 92.9, 92.8, 69.6, 52.4, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.01; H, 6.25.

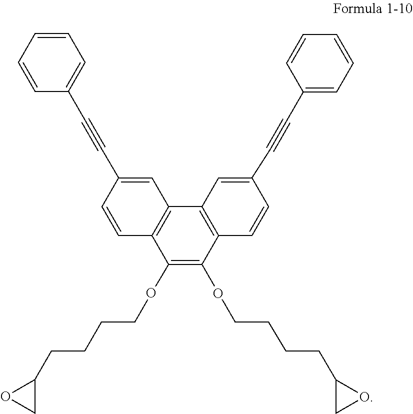 [SMILES: C(#Cc1ccc2c(OCCCCC3CO3)c(OCCCCC3CO3)c3ccc(C#Cc4ccccc4)cc3c2c1)c1ccccc1]

### Preparative Example 6: Preparation of Epoxy Resin

In a 250 ml flask, 1,8-dibromo-2,7-phenanthrenediol (36 g, 0.1 mol), 1-ethynyl-4-methoxybenzene (26 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 1,8-bis((4-Methoxyphenyl) ethynyl)-2,7-phenanthrenediol (E6). In the presence of TBAB (26 g, 0.1 mol) and an excess of 2-(4-chlorobutyl)oxirane (320 g), E6 (22 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-11 in 60% yield. ¹H NMR (400 MHz, CDCl₃) δ 8.75 (dd, 2H), 7.71 (s, 2H), 7.35 (m, 6H), 6.73 (m, 4H), 4.04 (m, 4H), 3.73 (s, 6H), 2.63-2.38 (m, 6H) 1.71 (m, 4H) 1.42 (m, 4H), 1.29 (m, 4H) ppm; ¹³C NMR (100 MHz, CDCl₃) δ 160.4, 160.2, 133.3, 133.2, 126.6, 122.7, 122.6, 115.0, 113.9, 113.8, 109.2, 107.8, 92.9, 92.8, 68.3, 55.9, 52.3, 47.9, 33.5, 33.2, 29.4, 21.6 ppm; GC-MS m/z=666 (M+); Anal. Calcd for C₄₄H₄₂O₆: C, 79.25; H, 6.35. Found: C, 79.43; H, 6.61.

### Formula 1-11

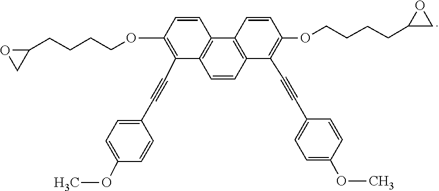 [SMILES: COc1ccc(C#Cc2c(OCCCCC3CO3)ccc3c2ccc2c(C#Cc4ccc(OC)cc4)c(OCCCCC4CO4)ccc23)cc1]

Details of components used in the following examples and comparative examples are as follows.
(A) Epoxy Resin
(A1) Epoxy resin prepared in Preparative Example 1
(A2) Epoxy resin prepared in Preparative Example 2
(A3) Epoxy resin prepared in Preparative Example 3
(A4) Epoxy resin prepared in Preparative Example 4
(A5) Epoxy resin prepared in Preparative Example 5
(A6) Epoxy resin prepared in Preparative Example 6
(A7) The following epoxy resin

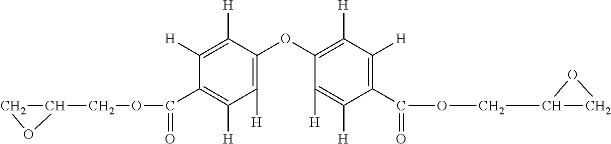 [SMILES: O=C(OCC1CO1)c1ccc(Oc2ccc(C(=O)OCC3CO3)cc2)cc1]

(A8) Biphenyl type epoxy resin (NC-3000, Nippon Kayaku Co., Ltd.)
(B) Curing agent
(B1) KPH-F3065 (Xylok type phenolic resin, Kolon Emulsion Co., Ltd.)
(B2) MEH-7851 (phenol aralkyl type phenol resin, Meiwa Co., Ltd.)
(C) Curing catalyst: Triphenyl phosphine (Hokko Chemical Co., Ltd.)
(D) Inorganic filler: A mixture of spherical fused alumina having an average particle diameter (D50) of 20 μm and spherical fused alumina having an average particle diameter (D50) of 0.5 μm (weight ratio: 9:1)
(E) Coupling agent
(E1) Methyltrimethoxysilane (SZ-6070, Dow Corning)
(E2) KBM-573 (N-phenyl-3-aminopropyltrimethoxysilane, Shin-etsu Chemical Co., Ltd.)
(F) Colorant: Carbon black (MA-600B, Mitsubishi Chemical Co., Ltd.).

### Examples 1 to 7 and Comparative Examples 1 to 4

The aforementioned components were uniformly mixed in amounts shown in Table 1 (unit: parts by weight) below in a Henschel mixer (KSM-22, Keumsung Machinery Co., Ltd.) at a temperature in a range of 25° C. to 30° C. for 30 min. Then, the mixture was subjected to melt-kneading in a continuous kneader at a temperature of up to 110° C. for 30 min, cooled to a temperature in a range of 10° C. to 15° C., and pulverized, thereby preparing epoxy resin compositions for encapsulation of semiconductor devices. Thereafter, 4.5 g of each of the epoxy resin compositions was placed in a tablet manufacturing device and compressed under a weight of 12 tons, thereby preparing a tablet encapsulation material having an outer diameter of Ψ 14 mm.

In Table 1 below, “-” means that a corresponding component was not used.

Each of the epoxy resin compositions prepared in Examples and Comparative Examples was evaluated as to the following properties. Results are shown in Table 1 below.
(1) Fluidity (spiral flow length, unit: inch): Using a low-pressure transfer molding machine, each of the prepared epoxy resin compositions was injected into a mold for measurement of fluidity under conditions of a mold temperature of 175° C., a load of 70 kgf/cm², an injection pressure of 9 MPa, and a curing time of 90 seconds in accordance with EMMI-1-66, followed by measurement of flow length. A greater flow length indicates better fluidity.
(2) Toughness (unit: kgf/mm²): In accordance with ASTM D-790, a standard specimen (125 mm×12.6 mm×6.4 mm (length×width×thickness)) was prepared from each of the epoxy resin compositions and cured at 175° C. for 4 hours, followed by measurement of toughness at 25° C. using a Universal Testing Machine (UTM).
(3) Thermal conductivity (unit: W/m·K): Thermal conductivity was measured on a specimen prepared from each of the prepared epoxy resin compositions at 25° C. in accordance with ASTM D5470. Specifically, a specimen for measurement of thermal conductivity was prepared in accordance with ASTM D5470 by injecting each of the epoxy resin compositions into a transfer molding machine under conditions of a mold temperature of 175° C., an injection pressure of 9 MPa, and a curing time of 120 seconds. Thereafter, thermal conductivity of the specimen was measured at 25° C. using a flash laser thermal conductivity meter (LFA467, NETZSCH Group).
(4) Reliability (Unit: number): A semiconductor package manufactured using each of the prepared epoxy resin compositions was dried at 125° C. for 24 hours and then subjected to 5 cycles of thermal shock testing (1 cycle being defined as leaving the package at −65° C. for 10 minutes, at 25° C. for 10 minutes, and at 150° C. for 10 minutes). Thereafter, the presence of external cracks was observed under an optical microscope after pre-conditioning treatment in which a process of leaving the package at 85° C. and 60% RH for 168 hours, followed by IR reflow at 260° C. for 30 seconds, was repeated three times. Thereafter, the occurrence of delamination between the epoxy resin composition and a lead frame was evaluated by scanning acoustic microscopy (C-SAM), which is a non-destructive testing method. Generation of external cracks in a semiconductor package or occurrence of delamination between the epoxy resin composition and the package indicates that the corresponding semiconductor package had poor reliability.

TABLE 1

| | | Example | | | | | | | Comparative Example | | | |
|---|---|---|---|---|---|---|---|---|---|---|---|---|
| | | 1 | 2 | 3 | 4 | 5 | 6 | 7 | 1 | 2 | 3 | 4 |
| (A) | (A1) | 5.2 | 5.2 | — | — | — | — | — | — | — | — | — |
| | (A2) | — | — | 5.2 | — | — | — | — | — | — | — | — |
| | (A3) | — | — | — | 5.2 | — | — | — | — | — | — | — |
| | (A4) | — | — | — | — | 5.2 | — | — | — | — | — | — |
| | (A5) | — | — | — | — | — | 5.2 | — | — | — | — | — |
| | (A6) | — | — | — | — | — | — | 5.2 | — | — | — | — |
| | (A7) | — | — | — | — | — | — | — | 5.2 | 5.2 | — | — |
| | (A8) | — | — | — | — | — | — | — | — | — | 5.2 | 5.2 |
| (B) | (B1) | 4.4 | — | 4.4 | 4.4 | 4.4 | 4.4 | 4.4 | 4.4 | — | 4.4 | — |
| | (B2) | — | 4.4 | — | — | — | — | — | — | 4.4 | — | 4.4 |
| (C) | | 0.5 | 0.5 | 0.5 | 0.5 | 0.5 | 0.5 | 0.5 | 0.5 | 0.5 | 0.5 | 0.5 |
| (D) | | 89 | 89 | 89 | 89 | 89 | 89 | 89 | 89 | 89 | 89 | 89 |
| (E) | (E1) | 0.2 | 0.2 | 0.2 | 0.2 | 0.2 | 0.2 | 0.2 | 0.2 | 0.2 | 0.2 | 0.2 |
| | (E2) | 0.2 | 0.2 | 0.2 | 0.2 | 0.2 | 0.2 | 0.2 | 0.2 | 0.2 | 0.2 | 0.2 |
| (F) | | 0.5 | 0.5 | 0.5 | 0.5 | 0.5 | 0.5 | 0.5 | 0.5 | 0.5 | 0.5 | 0.5 |
| Total | | 100 | 100 | 100 | 100 | 100 | 100 | 100 | 100 | 100 | 100 | 100 |
| Fluidity | | 67 | 66 | 67 | 69 | 70 | 68 | 67 | 66 | 66 | 65 | 65 |
| Toughness | | 0.87 | 0.89 | 1.01 | 0.90 | 0.91 | 0.87 | 0.81 | 0.49 | 0.52 | 0.45 | 0.50 |
| Thermal | | 7.0 | 7.2 | 6.4 | 6.8 | 6.9 | 7.2 | 6.9 | 5.1 | 5.3 | 4.6 | 4.7 |
| Conductivity | | | | | | | | | | | | |
| Reliability | External | 0 | 0 | 0 | 0 | 0 | 0 | 0 | 10 | 8 | 15 | 10 |
| | Crack | | | | | | | | | | | |
| | Delamination | 0 | 0 | 0 | 0 | 0 | 0 | 0 | 2 | 2 | 2 | 1 |
| | Number | 88 | 88 | 88 | 88 | 88 | 88 | 88 | 88 | 88 | 88 | 88 |
| | of | | | | | | | | | | | |
| | packages | | | | | | | | | | | |

As shown in Table 1 above, the epoxy resin compositions of the Examples exhibited good fluidity to allow easy encapsulation of semiconductor devices, exhibited good heat dissipation to reduce or suppress package malfunction and failure due to heat, and could reduce or suppress chip breakage and cracking of a semiconductor package due to external impact and stress in reliability evaluation.

Conversely, the epoxy resin compositions of the Comparative Examples prepared without using the epoxy resin represented by Formula 1 had lower toughness and thermal conductivity and poorer reliability than the epoxy resin compositions of Examples.

### Preparative Example 7: Preparation of Epoxy Resin

In a 250 ml flask, 1,5-dibromo-2,6-antracenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 1,5-bis(phenylethynyl)-2,6-annthracendiol (E7). In the presence of TBAB (26 g, 0.1 mol) and an excess (300 g) of 2-(4-chlorobutyl)oxirane, E7 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-12 in 75% yield. ¹H NMR (400 MHz, CDCl₃) δ 7.62 (s, 2H), 7.53 (m, 2H), 7.46 (m, 4H), 7.22-7.18 (m, 6H), 7.0 (m, 2H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 161.3, 138.4, 138.3, 137.4, 137.3, 132.3, 132.1, 129.5, 128.5, 128.4, 127.5, 127.4, 122.7, 119.1, 99.6, 92.9. 92.8, 68.9, 68.8, 52.3, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.58; H, 6.35.

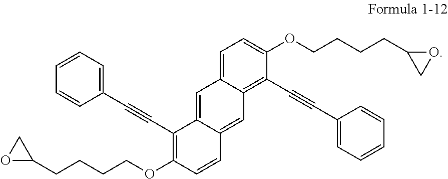 [SMILES: C(#Cc1c(OCCCCC2CO2)ccc2cc3c(C#Cc4ccccc4)c(OCCCCC4CO4)ccc3cc12)c1ccccc1]

### Preparative Example 8: Preparation of Epoxy Resin

In a 250 ml flask, 1,5-dibromo-2,6-antracenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 1,5-bis(phenylethynyl)-2,6-annthracendiol (E8). In the presence of with TBAB (26 g, 0.1 mol) and an excess of 2-(6-chlorohexyl)oxirane (320 g), E8 (21 g, 0.05 mol) was heated (to 90° C.) under solvent-free conditions for 6 hours and cooled to room temperature, followed by removing the remaining 2-(6-chlorohexyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-13 in 60% yield. ¹H NMR (400 MHz, CDCl₃) δ 7.62 (s, 2H), 7.53 (m, 2H), 7.46 (m, 4H), 7.22-7.18 (m, 6H), 7.0 (m, 2H), 4.04 (m, 4H), 2.63-2.38 (m, 6H) 1.71 (m, 4H) 1.42 (m, 4H), 1.31-1.27 (m, 12H) ppm; ¹³C NMR (100 MHz, CDCl₃) δ 161.3, 138.4, 138.3, 137.4, 137.3, 132.3, 132.1, 129.5, 128.5, 128.4, 127.5, 127.4, 122.7, 119.1, 99.6, 92.9. 92.8, 68.9, 68.8, 52.3, 47.9, 33.5, 33.2, 29.7, 29.4, 26.0, 25.3 ppm; GC-MS m/z=662 (M+); Anal. Calcd for C₄₆H₄₆O₄: C, 83.35; H, 6.99. Found: C, 83.51; H, 6.81.

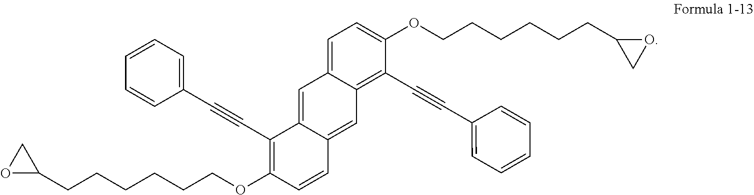 [SMILES: C(#Cc1c(OCCCCCCC2CO2)ccc2cc3c(C#Cc4ccccc4)c(OCCCCCCC4CO4)ccc3cc12)c1ccccc1]

### Preparative Example 9: Preparation of Epoxy Resin

In a 250 ml flask, 3,7-dibromo-2,6-anthracenediol (36 g, 0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 3,7-bis(phenylethynyl)-2,6-annthracendiol (E9). In the presence of TBAB (26 g, 0.1 mol) and an excess (300 g) of 2-(4-chlorobutyl)oxirane, E9 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the resulting product obtained through the synthesis process, followed by heating the reaction product to 90° C. for 4 hours, thereby preparing an epoxy resin represented by Formula 1-14 in 65% yield. ¹H NMR (400 MHz, CDCl₃)) δ 7.80 (s, 2H), 7.62 (s, 2H), 7.46 (m, 4H), 7.22-7.18 (m, 6H), 6.93 (m, 2H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 161.3, 133.3, 132.3, 132.2, 132.1, 129.5, 129.1, 128.6 128.5, 128.4, 126.5, 126.4, 122.7, 112.6, 105.5, 92.9, 92.8, 68.3, 68.2, 52.3, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.28; H, 6.47.

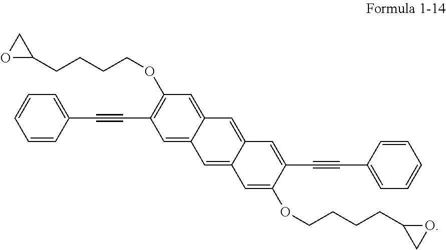 [SMILES: C(#Cc1cc2cc3cc(OCCCCC4CO4)c(C#Cc4ccccc4)cc3cc2cc1OCCCCC1CO1)c1ccccc1]

### Preparative Example 10: Preparation of Epoxy Resin

In a 250 ml flask, 1,5-dibromo-2,6-antracenediol (36 g, 0.1 mol), 1-ethynyl-4-methoxybenzene (26 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 1,5-bis((4-methoxyphenyl) ethynyl)-2,6-annthracendiol (E10). In the presence of TBAB (26 g, 0.1 mol) and an excess of 2-(4-chlorobutyl)oxirane (320 g), E10 (22 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-15 in 60% yield. ¹H NMR (400 MHz, CDCl₃) δ 7.62 (s, 2H), 7.53 (m, 2H), 7.35 (m, 4H), 7.0 (m, 2H), 6.73 (m, 4H), 4.04 (m, 4H), 3.73 (s, 6H), 2.63-2.38 (m, 6H) 1.71 (m, 4H) 1.42 (m, 4H), 1.31-1.27 (m, 12H) ppm; ¹³C NMR (100 MHz, CDCl₃) δ 161.3, 160.4, 138.4, 138.3, 133.5, 133.4, 133.3, 129.5, 127.5, 127.4, 122.7, 119.1, 115.1, 113.9, 113.8, 99.6, 92.9. 92.8, 68.9, 68.8, 55.9, 52.3, 47.9, 33.5, 29.7, 29.4, 21.6 ppm; GC-MS m/z=666 (M+); Anal. Calcd for C₄₄H₄₂O₆: C, 79.25; H, 6.35. Found: C, 79.39; H, 6.67.

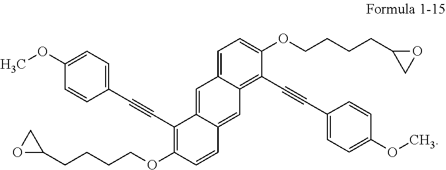 [SMILES: COc1ccc(C#Cc2c(OCCCCC3CO3)ccc3cc4c(C#Cc5ccc(OC)cc5)c(OCCCCC5CO5)ccc4cc23)cc1]

### Preparative Example 11: Preparation of Epoxy Resin

In a 250 ml flask, 9,10-dibromo-2,6-anthracenediol (36 g,0.1 mol), phenylacetylene (22 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 9,10-bis(phenylethynyl)-2,6-annthracendiol (E11). In the presence of TBAB (26 g, 0.1 mol) and an excess (300 g) of 2-(4-chlorobutyl)oxirane, E11 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction obtained through the synthesis process, followed by heating the reaction product (to 90° C.) for 4 hours, thereby preparing an epoxy resin represented by Formula 1-16 in 65% yield through intramolecular Williamson ether synthesis. ¹H NMR (400 MHz, CDCl₃) δ 7.60 (m, 2H), 7.46 (m, 4H), 7.22-7.18 (m, 6H), 7.04 (m, 2H), 6.97 (m, 2H), 4.04 (m, 4H), 2.63-2.38 (m, 6H) 1.71 (m, 4H) 1.42 (m, 4H), 1.29 (m, 4H) ppm; ¹³C NMR (100 MHz, CDCl₃) δ 158.1, 133.3, 132.3, 132.2, 132.1, 129.5, 129.1, 128.6 128.5, 128.4, 122.7, 120.5, 119.5, 106.5, 92.9, 92.8, 68.3, 68.2, 52.3, 47.9, 33.5, 33.2, 29.4, 21.6 ppm; GC-MS m/z=606 (M+); Anal. Calcd for C₄₂H₃₈O₄: C, 83.14; H, 6.31. Found: C, 83.44; H, 6.49.

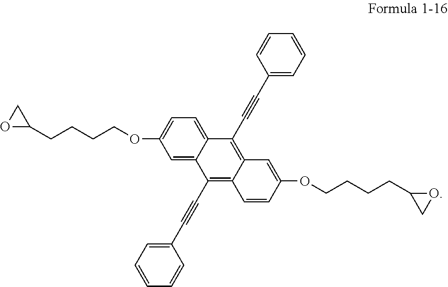 [SMILES: C(#Cc1c2ccc(OCCCCC3CO3)cc2c(C#Cc2ccccc2)c2ccc(OCCCCC3CO3)cc12)c1ccccc1]

### Preparative Example 12: Preparation of Epoxy Resin

In a 250 ml flask, 9,10-dibromo-2,6-anthracenediol (36 g, 0.1 mol), 1-ethynyl-3,5-dimethylbenzene (26 g, 0.22 mol), Pd(PPh₃)₂Cl₂ (3.0 g), CuI (10.0 g), and 50 ml of triethylamine were placed and reacted at 90° C. for 6 hours, followed by removing triethylamine using a distillation column. Then, 50 mL of diethyl ether was added to the reaction product to produce a soluble material, followed by removing the solvent therefrom, thereby preparing 9,10-bis((3,5-dimethylphenyl) ethynyl)-2,6-annthracendiol (E12). In the presence of TBAB (26 g, 0.1 mol) and an excess (300 g) of 2-(4-chlorobutyl)oxirane, E12 (21 g, 0.05 mol) was heated (to 90° C.) under solvent-free conditions for 6 hours and cooled to room temperature, followed by removing the remaining 2-(4-chlorobutyl)oxirane using a Kugelrohr distillation apparatus. Then, an aqueous solution of NaOH and toluene were added to the reaction product obtained through the synthesis process, followed by heating the reaction product (to 90° C.) for 4 hours, thereby preparing an epoxy resin represented by Formula 1-17 in 60% yield. ¹H NMR (400 MHz, CDCl₃) δ 7.60 (m, 2H), 7.07 (m, 4H), 7.04 (m, 2H), 6.97 (m, 2H), 6.79 (m, 2H), 4.04 (m, 4H), 2.63-2.38 (m, 6H), 2.35 (s, 12H), 1.71 (m, 4H) 1.42 (m, 4H), 1.29 (m, 4H) ppm; ¹³C NMR (100 MHz, CDCl₃) δ 158.1, 137.9, 137.8, 133.3, 132.3, 132.2, 132.1, 130.3, 130.2, 129.8, 129.7, 122.7, 120.5, 119.5, 106.5, 92.9, 92.8, 68.3, 68.2, 52.3, 47.9, 33.5, 33.2, 29.4, 24.0, 21.6 ppm; GC-MS m/z=662 (M+); Anal. Calcd for C₄₆H₄₆O₄: C, 83.35; H, 6.99. Found: C, 83.44; H, 6.68.

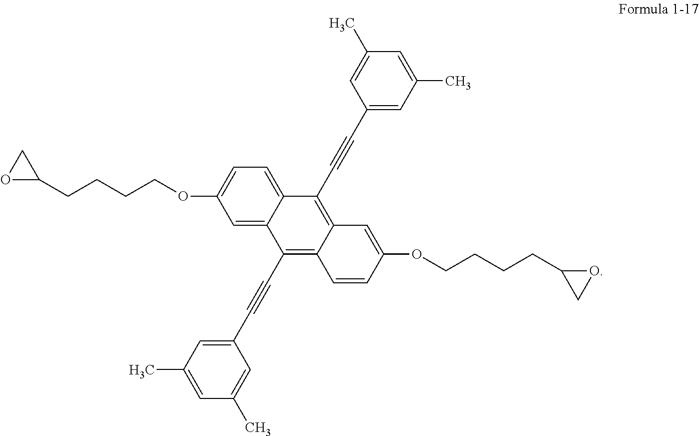 [SMILES: Cc1cc(C)cc(C#Cc2c3ccc(OCCCCC4CO4)cc3c(C#Cc3cc(C)cc(C)c3)c3ccc(OCCCCC4CO4)cc23)c1]

Details of components used in the following examples and comparative examples are as follows. Properties shown in Table 2 below were evaluated in the same manner as in Table 1 above.
(A) Epoxy resin
(A1) Epoxy resin prepared in Preparative Example 7
(A2) Epoxy resin prepared in Preparative Example 8
(A3) Epoxy resin prepared in Preparative Example 9
(A4) Epoxy resin prepared in Preparative Example 10
(A5) Epoxy resin prepared in Preparative Example 11
(A6) Epoxy resin prepared in Preparative Example 12
(A7), (A8), (B1), (B2), (C), (D), E1), E2), and (F) are the same as those described above with regard to Table 1 above.

TABLE 2

| | | Example | | | | | | | Comparative Example | | | |
|---|---|---|---|---|---|---|---|---|---|---|---|---|
| | | 8 | 9 | 10 | 11 | 12 | 13 | 14 | 5 | 6 | 7 | 8 |
| (A) | (A1) | 5.2 | 5.2 | — | — | — | — | — | — | — | — | — |
| | (A2) | — | — | 5.2 | — | — | — | — | — | — | — | — |
| | (A3) | — | — | — | 5.2 | — | — | — | — | — | — | — |
| | (A4) | — | — | — | — | 5.2 | | | — | — | — | — |
| | (A5) | — | — | — | — | — | 5.2 | — | — | — | — | — |
| | (A6) | — | — | — | — | — | — | 5.2 | — | — | — | — |
| | (A7) | — | — | — | — | — | — | — | 5.2 | 5.2 | — | — |
| | (A8) | — | — | — | — | — | — | — | — | — | 5.2 | 5.2 |
| (B) | (B1) | 4.4 | — | 4.4 | 4.4 | 4.4 | 4.4 | 4.4 | 4.4 | — | 4.4 | — |
| | (B2) | — | 4.4 | — | — | — | — | — | — | 4.4 | — | 4.4 |
| (C) | | 0.5 | 0.5 | 0.5 | 0.5 | 0.5 | 0.5 | 0.5 | 0.5 | 0.5 | 0.5 | 0.5 |
| (D) | | 89 | 89 | 89 | 89 | 89 | 89 | 89 | 89 | 89 | 89 | 89 |
| (E) | (E1) | 0.2 | 0.2 | 0.2 | 0.2 | 0.2 | 0.2 | 0.2 | 0.2 | 0.2 | 0.2 | 0.2 |
| | (E2) | 0.2 | 0.2 | 0.2 | 0.2 | 0.2 | 0.2 | 0.2 | 0.2 | 0.2 | 0.2 | 0.2 |
| (F) | | 0.5 | 0.5 | 0.5 | 0.5 | 0.5 | 0.5 | 0.5 | 0.5 | 0.5 | 0.5 | 0.5 |
| Total | | 100 | 100 | 100 | 100 | 100 | 100 | 100 | 100 | 100 | 100 | 100 |
| Fluidity | | 67 | 66 | 67 | 69 | 70 | 68 | 67 | 66 | 66 | 65 | 65 |
| Toughness | | 0.77 | 0.88 | 0.78 | 0.80 | 0.81 | 0.77 | 0.70 | 0.49 | 0.52 | 0.45 | 0.50 |
| Thermal | | 6.5 | 6.8 | 6.3 | 6.5 | 6.7 | 6.3 | 6.4 | 5.1 | 5.3 | 4.6 | 4.7 |
| conductivity | | | | | | | | | | | | |
| Reliability | External | 0 | 0 | 0 | 0 | 0 | 0 | 0 | 10 | 8 | 15 | 10 |
| | Crack | | | | | | | | | | | |
| | Delamination | 0 | 0 | 0 | 0 | 0 | 0 | 0 | 2 | 2 | 2 | 1 |
| | Number | 88 | 88 | 88 | 88 | 88 | 88 | 88 | 88 | 88 | 88 | 88 |
| | of | | | | | | | | | | | |
| | packages | | | | | | | | | | | |

As shown in Table 2 above, the epoxy resin compositions of the Examples exhibited good fluidity to allow easy encapsulation of semiconductor devices, exhibited good heat dissipation to reduce or suppress package malfunction and failure due to heat, and could reduce or suppress chip breakage and cracking of a semiconductor package due to external impact and stress in reliability evaluation.

Conversely, the epoxy resin compositions of the Comparative Examples prepared without using the epoxy resin represented by Formula 1 had lower toughness and thermal conductivity, and poorer reliability, than the epoxy resin compositions of Examples.

It should be understood that various modifications, changes, alterations, and equivalent embodiments can be made by those skilled in the art without departing from the spirit and scope of the disclosure.

What is claimed is:

1. An epoxy resin composition comprising:
an epoxy resin;
a curing agent;
one or more inorganic fillers; and
a curing catalyst;
wherein the epoxy resin comprises an epoxy resin represented by Formula 1: 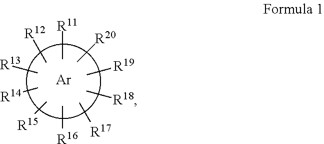
where Ar comprises anthracene or phenanthrene, and
R¹¹ to R²⁰ are each independently hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, Formula 3, or Formula 4,
provided that at least one of R¹¹ to R²⁰ comprises Formula 2, or
at least one of R¹¹ to R²⁰ comprises Formula 3, and
at least two of R¹¹ to R²⁰ comprise Formula 4; 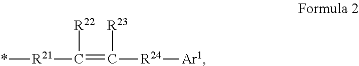
where * is a linking site of an element,
R²¹ and R²⁴ are each independently a single bond or a substituted or unsubstituted C₁ to C₅ alkylene group,
R²² and R²³ are each independently hydrogen or a substituted or unsubstituted C₁ to C₅ alkyl group, and
Ar¹ comprises a substituted or unsubstituted C₆ to C₁₀ aryl group; 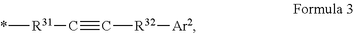
where * is a linking site of an element,
R³¹ and R³² are independently a single bond or a substituted or unsubstituted C₁ to C₅ alkylene group, and
Ar² comprises a substituted or unsubstituted C₆ to C₁₀ aryl group; 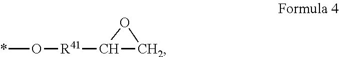
where * is a linking site of an element, and
R⁴¹ is a single bond or a substituted or unsubstituted C₁ to C₂₀ alkylene group.

2. The epoxy resin composition as claimed in claim 1, wherein the epoxy resin represented by Formula 1 comprises at least one of compounds represented by Formulas 1-2 and 1-3: 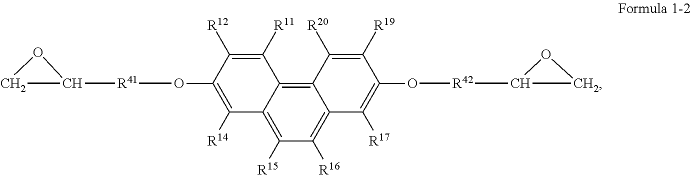
where R¹¹, R¹², R¹⁴, R¹⁵, R¹⁶, R¹⁷, R¹⁹, and R²⁰ are each independently hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, or Formula 3,
provided that at least one of R¹¹, R¹², R¹⁴, R¹⁵, R¹⁶, R¹⁷, R¹⁹, and R²⁰ comprises Formula 2, or
at least one of R¹¹, R¹², R¹⁴, R¹⁵, R¹⁶, R¹⁷, R¹⁹, and R²⁰ comprises Formula 3, and
R⁴¹ and R⁴² are each independently a single bond or a substituted or unsubstituted C₁ to C₂₀ alkylene group; 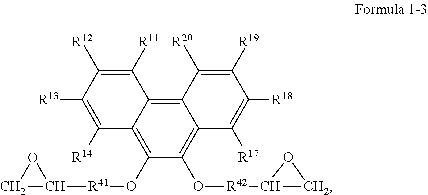
where R¹¹, R¹², R¹³, R¹⁴, R¹⁷, R¹⁸, R¹⁹, and R²⁰ are each independently hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, or Formula 3,
provided that at least one of R¹¹, R¹², R¹³, R¹⁴, R¹⁷, R¹⁸, R¹⁹, and R²⁰ comprises Formula 2, or
at least one of R¹¹, R¹², R¹³, R¹⁴, R¹⁷, R¹⁸, R¹⁹, and R²⁰ comprises Formula 3, and
R⁴¹ and R⁴² are each independently a single bond or a substituted or unsubstituted C₁ to C₂₀ alkylene group.

3. The epoxy resin composition as claimed in claim 1, wherein the epoxy resin represented by Formula 1 comprises at least one compound represented by Formulas 1-5: 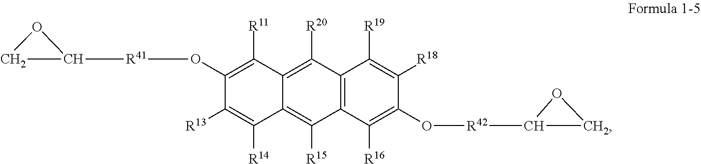
where R¹¹, R¹³, R¹⁴, R¹⁵, R¹⁶, R¹⁸, R¹⁹, and R²⁰ are each independently hydrogen, a halogen, an amino group, a substituted or unsubstituted C₁ to C₁₀ alkyl group, a substituted or unsubstituted C₂ to C₁₀ alkenyl group, a substituted or unsubstituted C₂ to C₁₀ alkynyl group, a substituted or unsubstituted C₆ to C₂₀ aryl group, a substituted or unsubstituted C₇ to C₂₀ arylalkyl group, Formula 2, or Formula 3,
provided that at least one of R¹¹, R¹³, R¹⁴, R¹⁵, R¹⁶, R¹⁸, R¹⁹, and R²⁰ comprises Formula 2, or
at least one of R¹¹, R¹³, R¹⁴, R¹⁵, R¹⁶, R¹⁸, R¹⁹, and R²⁰ comprises Formula 3, and
R⁴¹ and R⁴² are each independently a single bond or a substituted or unsubstituted C₁ to C₂₀ alkylene group.

4. The epoxy resin composition as claimed in claim 1, wherein the epoxy resin represented by Formula 1 comprises at least one of compounds represented by Formulas 1-6 to 1-17:

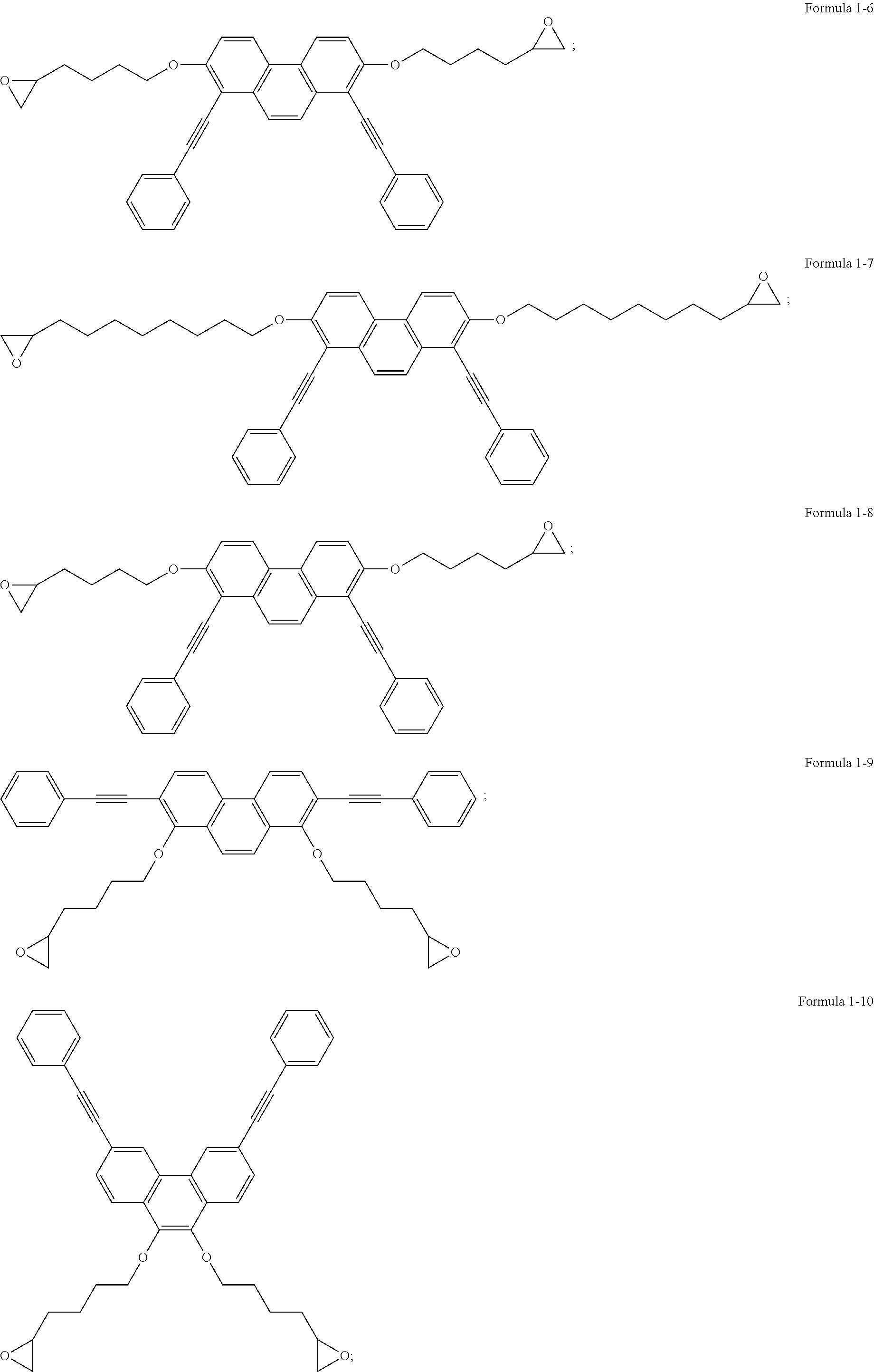

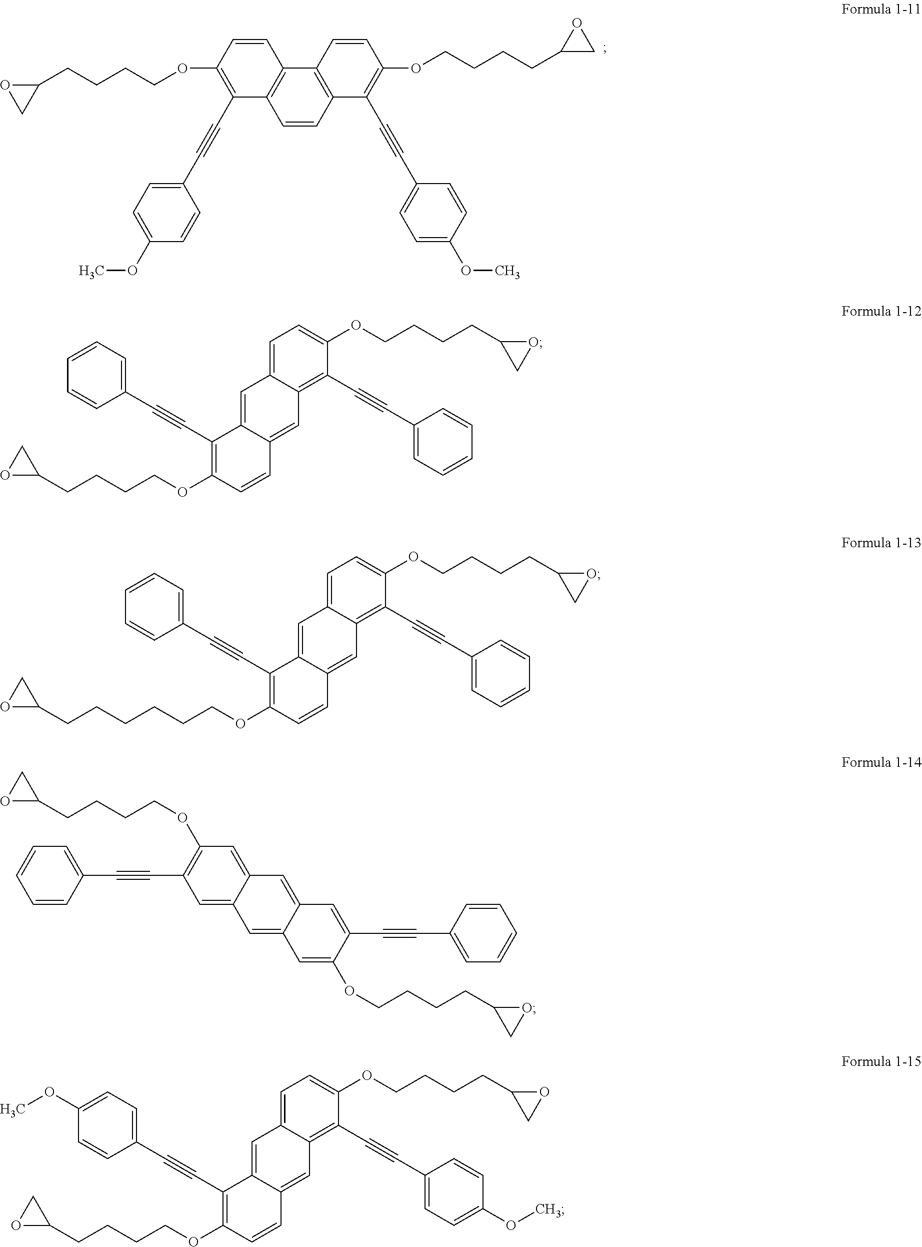 [SMILES: COc1ccc(C#Cc2c(OCCCCC3CO3)ccc3c2ccc2c(C#Cc4ccc(OC)cc4)c(OCCCCC4CO4)ccc23)cc1 ; C(#Cc1c(OCCCCC2CO2)ccc2cc3c(C#Cc4ccccc4)c(OCCCCC4CO4)ccc3cc12)c1ccccc1 ; C(#Cc1c(OCCCCCCC2CO2)ccc2cc3c(C#Cc4ccccc4)c(OCCCCC4CO4)ccc3cc12)c1ccccc1 ; C(#Cc1cc2cc3cc(OCCCCC4CO4)c(C#Cc4ccccc4)cc3cc2cc1OCCCCC1CO1)c1ccccc1 ; COc1ccc(C#Cc2c(OCCCCC3CO3)ccc3cc4c(C#Cc5ccc(OC)cc5)c(OCCCCC5CO5)ccc4cc23)cc1]

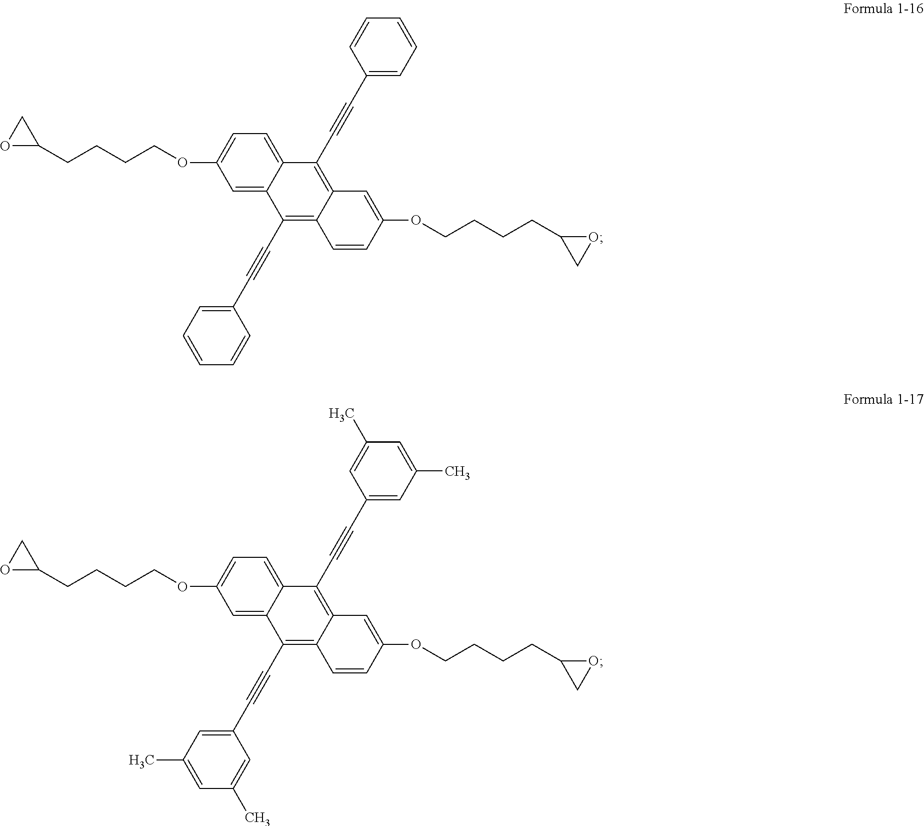 [SMILES: C(#Cc1c2ccc(OCCCCC3CO3)cc2c(C#Cc2ccccc2)c2ccc(OCCCCC3CO3)cc12)c1ccccc1 ; Cc1cc(C)cc(C#Cc2c3ccc(OCCCCC4CO4)cc3c(C#Cc3cc(C)cc(C)c3)c3ccc(OCCCCC4CO4)cc23)c1]

5. The epoxy resin composition as claimed in claim 1, wherein the epoxy resin represented by Formula 1 is present in an amount in a range of about of 0.1 wt % to about 17 wt % in the epoxy resin composition.

6. The epoxy resin composition as claimed in claim 1, comprising:
a range of about 2 wt % to about 17 wt % of the epoxy resin;
a range of about 0.5 wt % to about 13 wt % of the curing agent;
a range of about 50 wt % to about 95 wt % of the one or more inorganic fillers; and
a range of about 0.01 wt % to about 5 wt % of the curing catalyst.

7. A semiconductor device encapsulated using the epoxy resin composition for encapsulation of semiconductor devices as claimed in claim 1.
